(19) United States
(12) Patent Application Publication
(10) Pub. No.: US 2006/0134925 A1
(43) Pub. Date: Jun. 22, 2006

(54) Method of forming a gate insulating layer of a semiconductor device using deuterium gas

(76) Inventors: Jai-Dong Lee, Gyeonggi-do (KR); Jung-Hwan Kim, Gyeonggi-do (KR); Woong Lee, Seoul (KR); Hun-Hyeoung Leam, Gyeonggi-do (KR); Sang-Hun Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/302,892

(22) Filed: Dec. 13, 2005

(30) Foreign Application Priority Data
Dec. 17, 2004 (KR) 2004-107772

(51) Int. Cl. H01L 21/31; H01L 21/469

(52) U.S. Cl. 438/770; 438/787

(57) ABSTRACT

In an exemplary embodiment of the invention a method of forming a gate oxide layer of a semiconductor device uses deuterium gas. The method includes introducing a semiconductor substrate, and depositing an insulating layer on the semiconductor substrate by supplying an oxidation reaction gas and a deuterium gas to the semiconductor substrate. Thus, a high quality gate oxide layer can be formed and resistance to degradation from the hot carrier effect can be improved. Further, when the method is applied to a tunnel oxide layer process of a flash memory, problems such as an increasing dispersion of the threshold voltage can be mitigated.

### CROSS REFERENCE TO RELATED APPLICATIONS

This application claims priority from Korean Patent Application No. 2004-0107772, filed on Dec. 17, 2004, the contents of which are hereby incorporated by reference in their entirety for all purposes.

### BACKGROUND OF THE INVENTION

1. Field of the Invention

This disclosure generally relates to semiconductor manufacturing and, more particularly to, a method of forming a gate oxide layer of a semiconductor device using a deuterium gas.

2. Description of the Related Art

In a semiconductor device the thickness of a gate oxide layer has become thin as a result of high integration and capacity. Presently, a silicon oxide layer (SiO₂) is commonly used as a gate insulating layer. Such a silicon oxide layer has been widely used because of its thermal stability and reliability along with ease of manufacture. In particular, the silicon oxide layer is mostly used as a gate insulating layer when a silicon wafer is used as a semiconductor substrate, and it is fabricated by a so-called “pyro oxidation” process. Such a process may be to heat the silicon wafer to a high temperature in a vapor atmosphere generated from a reaction of oxygen and hydrogen by an ignition torch.

Because the gate insulating layer is becoming increasingly thin, the threshold voltage and hot carrier effect of the device incorporating the gate insulating layer is adversely affected. For example, when an SiO₂ layer is formed as a gate insulating layer on a silicon wafer by pyro oxidation, the Si/SiO₂ interface will end up having a relatively high amount of intervening hydrogen bonding unfortunately, hydrogen bonding is easily broken by a high electric in a hot carrier effect, and also causes a threshold voltage shift, thus affecting the functionality of the substrate. Accordingly, an improved method of forming a gate insulating layer is needed.

### SUMMARY

Exemplary embodiments of the invention provide a method of forming a gate insulating layer of a semiconductor device using a deuterium gas. An embodiment may include providing a semiconductor substrate; and depositing an insulating layer on the semiconductor substrate by supplying an oxidation reaction gas and a deuterium gas to the semiconductor substrate. Thus, a high quality gate oxide layer can be formed with an improved resistance to degradation by the hot carrier effect.

### BRIEF DESCRIPTION OF THE DRAWINGS

The above and other features of exemplary embodiments of the invention will become readily apparent from the description that follows, with reference to the attached drawings, in which:

FIG. 1 is a cross-sectional view illustrating a method of forming a gate oxide layer of a semiconductor device according to an exemplary embodiment of the invention;

FIGS. 2 to 5 are timing diagrams illustrating the method of forming the gate oxide layer shown in FIG. 1; and

FIG. 6 are photographs comparing thinning of an oxide layer formed using hydrogen with thinning of an oxide layer formed using deuterium.

### DETAILED DESCRIPTION OF THE PREFERRED EMBODIMENTS

Exemplary embodiments of the invention are more fully described in detail with reference to the accompanying drawings. The invention may be embodied in many different forms and should not be construed as being limited to the exemplary embodiments set forth herein. Rather, these exemplary embodiments are provided so that this disclosure is thorough and complete, and to convey the concept of the invention to those skilled in the art.

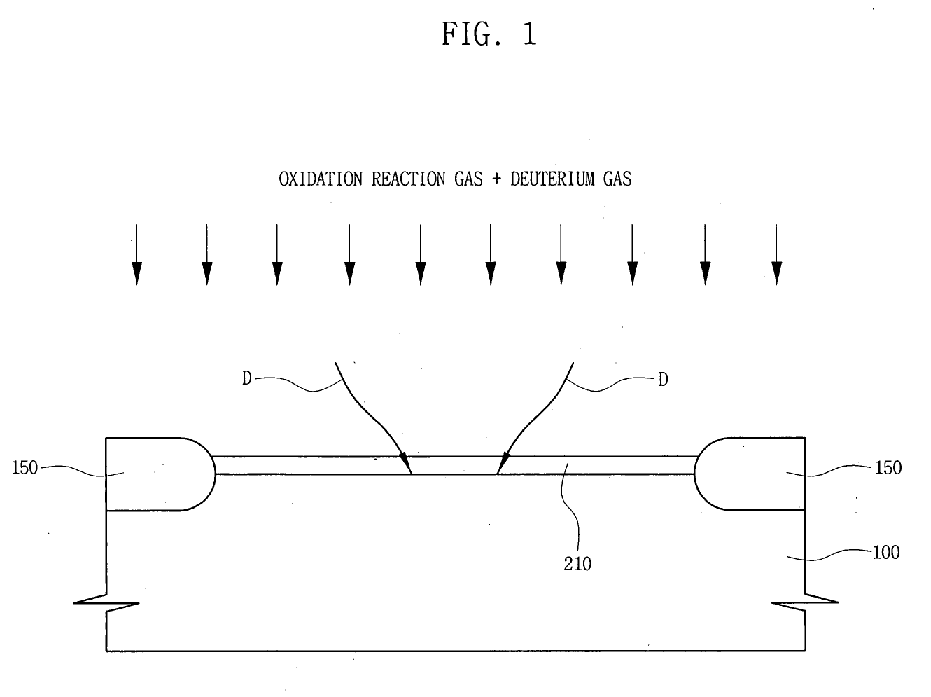

FIG. 1 is a cross-sectional view illustrating a method of forming a gate oxide layer of a semiconductor device according to an exemplary embodiment of the invention.

Referring to FIG. 1, a semiconductor substrate 100 is introduced into a chamber. A device isolation region 150 is formed on the semiconductor device.

Oxide reaction gas and deuterium gas are provided to the semiconductor substrate 100, thereby forming an oxide layer. Namely, the oxide reaction gas including O₂ or O₃ may be provided to the semiconductor substrate 100.

Explaining the notation used herein, D2 means deuterium, which has a mass number of 2, an atomic weight of 2.01409, and is an isotope of hydrogen. H2 means protium, having a mass number of 1, an atomic weight of 1.007, and is also an isotope of hydrogen.

Also, the term “dangling bonds” may refer to unsaturated silicon bonds, i.e., unfilled bonds. These dangling bonds occur primarily at surfaces or interfaces of devices or layers, but they can also occur elsewhere in the material.

The deuterium gas may be supplied with the reaction gas, may be successively supplied without an intervening vacuum break, or an inert gas may be supplied with the deuterium gas. Any combination of these options, and others, is possible.

Exemplary embodiments regarding a process for forming a gate insulating layer 210 including supplying an oxide reaction gas and deuterium gas are more fully described in detail with reference to the accompanied timing diagrams.

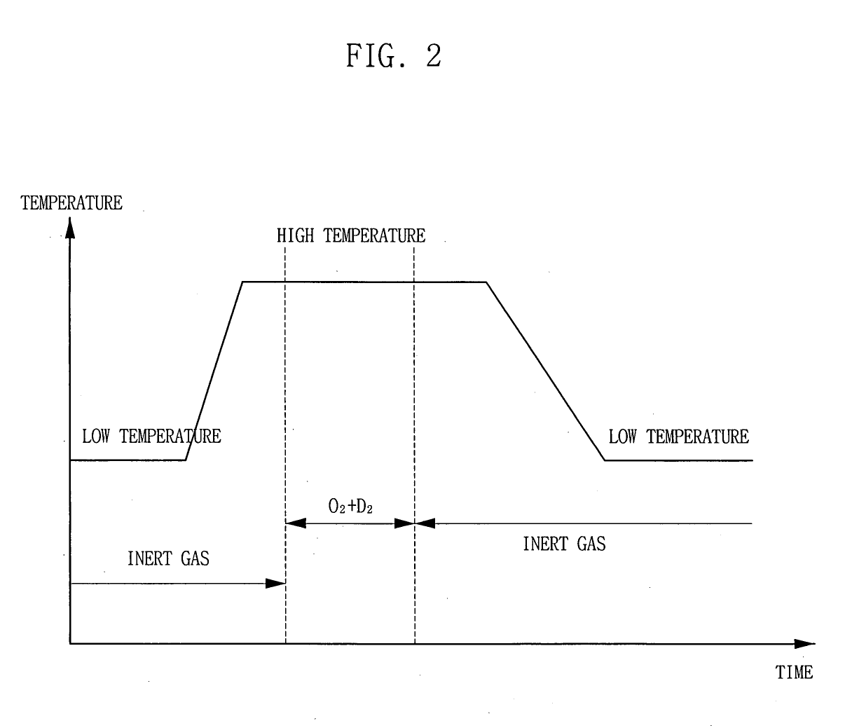

FIGS. 2 through 5 are timing diagrams illustrating a method of forming the gate oxide layer shown in FIG. 1

Referring to FIG. 2, a stand-by state with a low temperature is maintained for a predetermined time after the semiconductor substrate (100 of FIG. 1) is introduced. For forming the gate oxide layer 210, the stand-by state may be maintained at a low temperature of about 400° C. to about 500° C. At this time, an ambient atmosphere may include an inert gas.

Afterwards, the temperature is raised to a relatively high temperature. For example, this temperature may be maintained at about 800° C. to about 1000° C. during the process of forming the oxide layer. An oxide atmosphere such as an oxygen gas is provided on the semiconductor substrate 100 to form the gate oxide layer 210, thereby oxidizing surface silicon of the semiconductor substrate 100.

At this time, the oxygen gas and the deuterium gas may be supplied together: To form the gate oxide layer 210, the oxygen gas for the oxide reaction and the deuterium gas are used together. As a result, the gate oxide layer 210 is formed by silicon oxidation, and deuterium (D of FIG. 1) which diffuses and penetrates the gate oxide layer is combined with dangling bonds located at the semiconductor substrate 100 and an interface of the gate oxide layer 210. The deuterium diffuses into the gate oxide layer 210, with a high efficiency of combining with dangling bonds after reaching the interface.

Then, the stand-by state is again maintained by lowering the temperature of the semiconductor substrate 100. The ambient atmosphere preferably includes an inert gas.

Referring to FIG. 2, the oxygen gas and the deuterium gas may be supplied together in the atmosphere when forming the gate oxide layer 210 without an intervening vacuum break, namely, the deuterium gas may be successively supplied. In other words, the pressure conditions present for the oxygen gas may be substantially the same as for the deuterium gas.

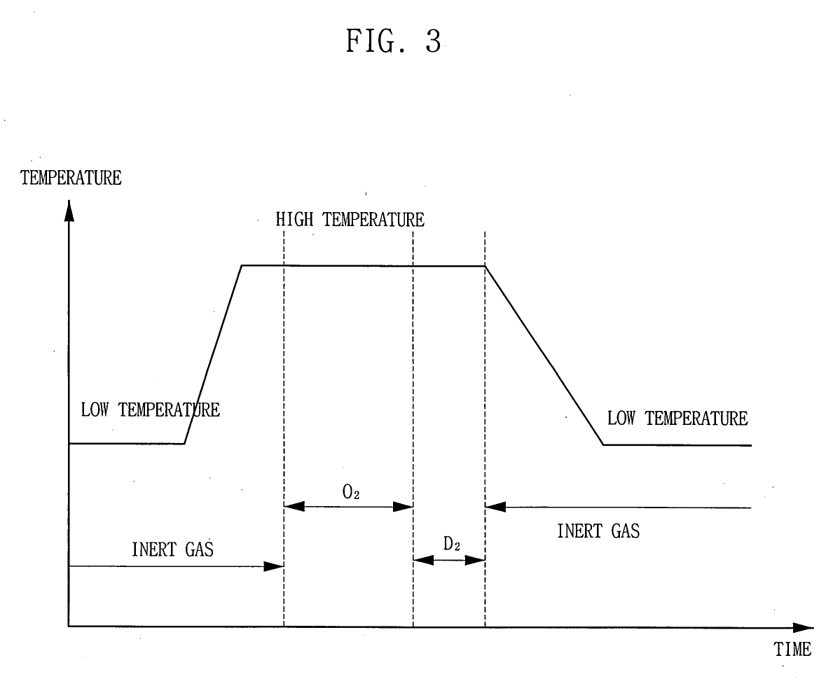

Referring to FIG. 3, the oxygen gas for the oxidizing reaction is supplied to the semiconductor substrate 100 while maintaining a high temperature. Then the deuterium gas may be supplied to the semiconductor substrate 100 without an intervening vacuum break. Deuterium from the supplied deuterium gas may be combined with dangling bonds at or near the interface by diffusing and penetrating the gate oxide layer 210 formed by supplying the oxygen gas. Since the direction and distance of the diffusing is only through the thickness of the gate oxide layer 210, deuterium may be combined with dangling bonds with a high efficiency. In the meantime, the semiconductor substrate 100 may be maintained at a high temperature while providing the deuterium gas. Further, the deuterium gas may be provided in a diluted state by an inert gas.

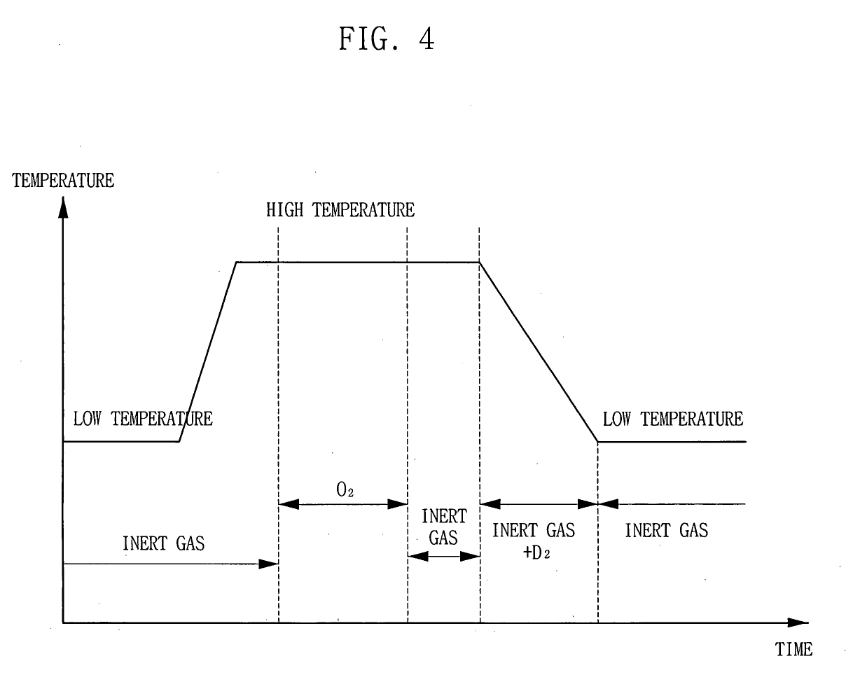

Referring to FIG. 4, an inert gas is provided before providing the deuterium gas without an intervening vacuum break, thereby purging the inside of the chamber in which the semiconductor substrate 100 is mounted. The deuterium gas diluted by the inert gas may be supplied during the process of lowering the temperature in a stand-by state.

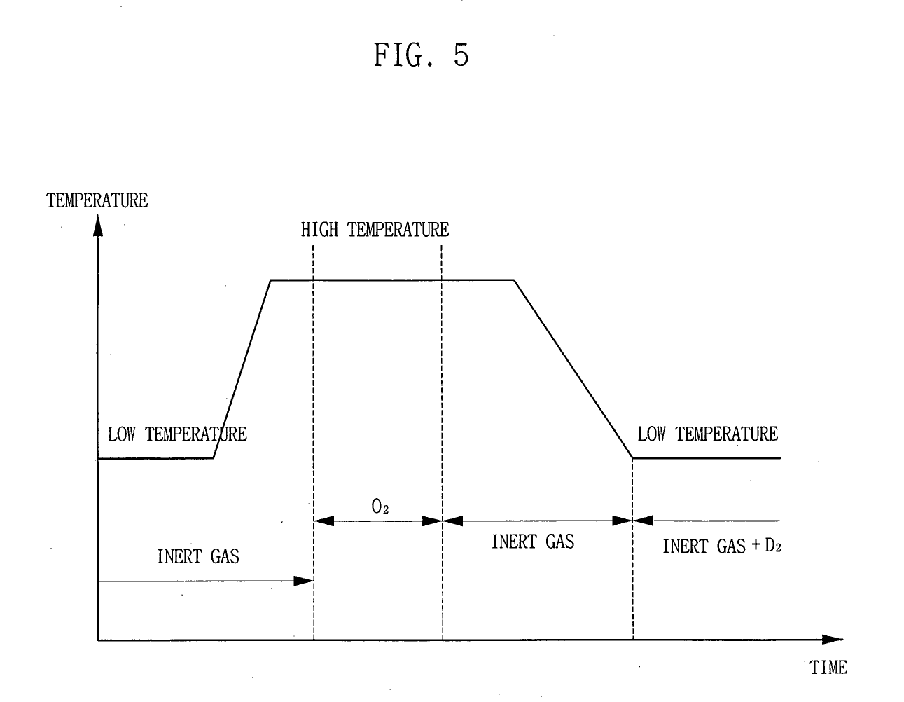

Referring to FIG. 5, a diluted deuterium gas or an inert gas, or their combination, may be provided into a chamber after a high temperature reaction process is completed. Or these gases may be provided to the semiconductor substrate 100 after the temperature of the semiconductor substrate 100 is lowered to a low temperature in the stand-by state. At this time, the inside of the chamber may be purged by providing an inert gas while lowering the temperature.

Referring to FIG. 2 through FIG. 5, if the process of diluting the deuterium gas with the inert gas and the process of forming the gate oxide layer 210 are carried out at the same time, then the deuterium gas may diffuse more readily to reach, and combine with, the dangling bonds, particularly at the gate oxide layer 210 and the semiconductor substrate 100 interface.

Further, the pyro oxidation process may be used to form the gate oxide layer of the semiconductor device.

Hereinafter, according to one embodiment, a method of forming the gate oxide layer of the semiconductor device by the pyro oxidation process using the deuterium gas will be explained. Deuterium (D₂) and oxygen (O₂), as a gas for the pyro oxidation, are injected into the chamber. At this time, D₂ and O₂ are activated with a plasma generator, thereby forming D_{2*} and O_{2*}, respectively. Since D_{2*} and O_{2*} injected in the inside of the chamber are in an active state, they become mostly a vapor of deuterium oxide (D₂O) by mutually reacting without the ignition torch and a relatively small amount of D_{2*} and O_{2*}, which do not react to expedite the oxidation process of the silicon wafer surface.

In the process of forming the gate oxide layer, namely the silicon oxide layer, in accordance with this exemplary embodiment of the present invention, D₂O increases the solubility of O₂ on the silicon wafer, thereby increasing the rate of growth of the oxide layer. D₂, which does not react with O₂, causes a D_{2*} annealing effect at a low temperature of the silicon wafer. Since such an oxidation process is the surface state reaction in which the activated D_{2*} and O_{2*} participate, a high layer quality may be maintained, even though the silicon oxide layer is formed at a low temperature compared with a conventional pyro oxidation process using only H₂ and O₂. Also, the oxide layer having a sufficient thickness may be formed even at a relatively low temperature due to a high growth rate of the oxide layer. Accordingly, if the silicon wafer is heated with a heater installed in the chamber, then the pyro oxidation process may proceed at the wafer temperature of, say, 650° C., which is lower than the conventional pyro oxidation process that uses only H₂ and O₂.

In the method of forming the oxide layer using deuterium, the silicon and silicon dangling bonds existing at or near the interface of the gate oxide layer of SiO₂ form into SiO₂ with an Si-D bond which is stronger than an Si—H bond. Thus, the gate oxide layer will be formed with high quality and resistance to hot carrier degradation. Further, since this method may proceed at a relatively low temperature, a difficulty of controlling the threshold voltage can be alleviated by an external diffusion of doping into a lower part of the gate oxide layer.

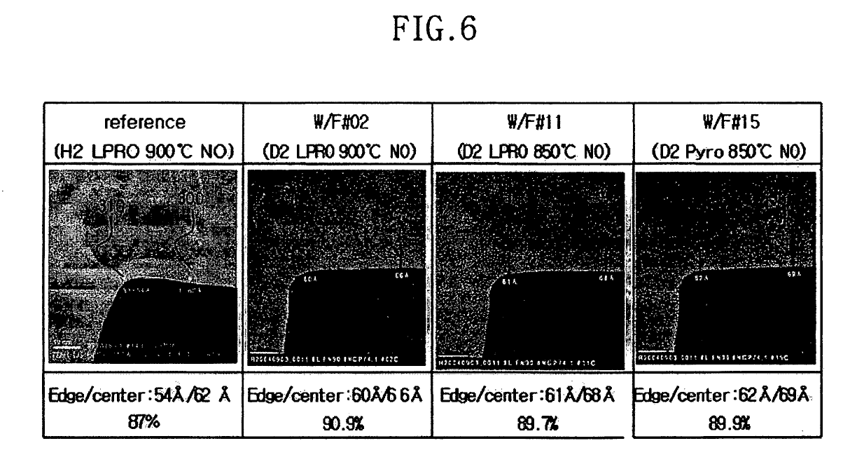

FIG. 6 are photographs comparing thinning of oxide layers formed using hydrogen and deuterium.

FIG. 6A is a photograph of the oxide layer formed using hydrogen. FIGS. 6B, 6C, and 6D are photographs of the oxide layer formed using deuterium. Referring to FIG. 6A, the thickness of the oxide layer 300 in a center region is 62 Å and a thickness of the oxide layer 310 in an edge region is 54 Å. The thickness of the oxide layer in the edge region is 87% of the thickness of the oxide layer in the center region. In comparison, as shown in FIG. 6B, the thickness of the oxide layer 320 formed in a central portion using deuterium is 66 Å and the thickness of the oxide layer 330 in the edge region is 60 Å. So, the thickness of the oxide layer in the edge region is 90.9% compared with the thickness of the oxide layer in the center region. A thickness of the oxide layer in the center region 340 formed using deuterium as shown in FIG. 6C is 68 Å and a thickness of the oxide layer in the edge region 350 is 61 Å. So, the thickness of the oxide layer in the edge region is 89.7% compared with the thickness of the oxide layer in the center region. A thickness of the oxide layer in the center region 360 formed using deuterium as shown in FIG. 6D is 69 Å and a thickness of the oxide layer in the edge region 370 is 62 Å. Namely, the thickness of the oxide layer in the edge region is 89.9% compared with the thickness in the center region.

As shown, maintaining the thickness of the edge portion of the oxide layer is improved when the oxide layer is formed using deuterium rather than hydrogen. For instance, in this case, there is a 2% improvement by providing D₂ in place of hydrogen. Thus, the quality of the gate oxide layer can be improved this way.

It will be apparent to those skilled in the art that modifications and variations may be made in these embodiments of the present invention without deviating from the spirit or scope of the invention. Thus, the invention is not limited by the exemplary embodiments described above, but rather by the attached claims which encompass all such modifications and equivalents.

What is claimed is:

1. A method of forming a gate oxide layer of a semiconductor device, the method comprising:
providing a semiconductor substrate; and
supplying an oxidation reaction gas and a deuterium gas to the semiconductor substrate to deposit an insulating layer thereon.

2. The method of claim 1, wherein the depositing of the insulating layer comprises supplying both the oxidation reaction gas and the deuterium gas to the semiconductor substrate.

3. The method of claim 1, wherein after the oxidation reaction gas is supplied to the semiconductor substrate, the deuterium gas is successively supplied to the semiconductor substrate, in situ.

4. A method of forming a gate oxide layer of a semiconductor device, the method comprising:
introducing deuterium and oxygen sequentially into a reaction chamber, respectively;
making a deuterium oxygen vapor from the deuterium and the oxygen by a pyro reaction; and
heating a silicon wafer in the deuterium oxygen vapor, thereby forming a silicon oxygen layer on a silicon wafer surface.

5. The method of claim 4, wherein while forming the silicon oxygen layer, the wafer is maintained at a predetermined temperature of from about 500 to about 950° C.

6. The method of claim 4, wherein the deuterium is supplied with an inert gas.

7. A method of forming an oxide layer of a semiconductor device, the method comprising:
providing a semiconductor substrate into a reaction chamber;
maintaining, for a first predetermined time, the semiconductor substrate at a low temperature in an inert gas;
exposing the semiconductor substrate to oxygen at a high temperature;
exposing the semiconductor substrate to deuterium gas at the high temperature; and
decreasing the temperature of the semiconductor substrate to the low temperature while exposing the semiconductor substrate to the inert gas.

8. The method of claim 7, further comprising maintaining the semiconductor substrate at the low temperature in the inert gas for a second predetermined time.

9. The method of claim 7, wherein the exposing the semiconductor substrate to the deuterium gas is performed after the exposing the semiconductor substrate to the oxygen gas.

10. The method of claim 7, wherein the exposing the semiconductor substrate to the deuterium gas is performed at the same time as the exposing the semiconductor substrate to the oxygen gas.

11. The method of claim 7, wherein the low temperature is between about 400 and about 500 degrees C.

12. The method of claim 7, wherein the high temperature is between about 800 and about 1000 degrees C.

13. A method of forming an oxide layer of a semiconductor device, the method comprising:
providing a semiconductor substrate into a reaction chamber;
maintaining, for a first predetermined time, the semiconductor substrate at a low temperature in an inert gas;
exposing the semiconductor substrate to oxygen at a high temperature;
purging the oxygen gas from the reaction chamber by the inert gas; and
decreasing the temperature of the semiconductor substrate to the low temperature while exposing the semiconductor substrate to the inert gas and deuterium gas.

14. The method of claim 13, further comprising maintaining the semiconductor substrate at the low temperature in the inert gas for a second predetermined time.

15. The method of claim 13, wherein the temperature of the semiconductor substrate is decreased from the high temperature to the low temperature during the exposure of the semiconductor substrate to the deuterium gas.

16. A method of forming an oxide layer of the semiconductor device, the method comprising:
introducing a semiconductor substrate into a reaction chamber;
maintaining, for a first predetermined time, the semiconductor substrate at a low temperature in an inert gas;
exposing the semiconductor substrate to oxygen gas at a high temperature higher than the low temperature;
exposing the semiconductor substrate to the inert gas at the high temperature; and
decreasing the temperature of the semiconductor substrate to the low temperature while exposing the semiconductor substrate to the inert gas.

17. The method of claim 16, further comprising maintaining the semiconductor substrate at the low temperature while exposing the semiconductor substrate to the inert gas and deuterium gas for a second predetermined time.

18. The method of claim 16, wherein the low temperature is between about 400 and about 500 degrees C.

19. The method of claim 16, wherein the high temperature is between about 800 and about 1000 degrees C.
